(19) United States
(12) Patent Application Publication
(10) Pub. No.: US 2026/0235969 A1
(43) Pub. Date: Aug. 13, 2026

(54) DEBRIS TRAP, EXTREME ULTRAVIOLET LIGHT GENERATION APPARATUS, AND ELECTRONIC DEVICE MANUFACTURING METHOD

(71) Applicant: Gigaphoton Inc., Tochigi (JP)

(72) Inventors: Takayuki SUZUKI, Tochigi (JP); Atsushi UEDA, Tochigi (JP); Soichiro KONDO, Tochigi (JP)

(73) Assignee: Gigaphoton Inc., Tochigi (JP)

(21) Appl. No.: 19/440,558

(22) Filed: Jan. 5, 2026

(30) Foreign Application Priority Data
Feb. 13, 2025 (JP) 2025-021464

(51) Int. Cl. G03F 7/00

(52) U.S. Cl. CPC G03F 7/70916; G03F 7/70033

(57) ABSTRACT

A debris trap is arranged on an exhaust path including a gas inlet port through which a gas containing debris flows from a chamber and a gas exhaust port through which the gas is exhausted. The debris trap includes a first multi-tube and a second multi-tube arranged respectively along a first direction which is a flow direction of the gas traveling from the gas inlet port to the gas exhaust port. Each of the first multi-tube and the second multi-tube includes a plurality of tubes having different maximum outer dimensions in a second direction perpendicular to the first direction. The second multi-tube is arranged downstream of the first multi-tube in the first direction. A number of tubes configuring the second multi-tube is more than a number of tubes configuring the first multi-tube.

### CROSS-REFERENCE TO RELATED APPLICATIONS

The present application claims the benefit of Japanese Patent Application No. 2025-021464, filed on Feb. 13, 2025, the entire contents of which are hereby incorporated by reference.

### BACKGROUND

### 1. Technical Field

The present disclosure relates to a debris trap, an extreme ultraviolet light generation apparatus, and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: U.S. Pat. No. 8,067,757

Patent Document 2: Japanese Patent Application Publication No. H10-80617

### SUMMARY

A debris trap is arranged on an exhaust path including a gas inlet port through which a gas containing debris flows from a chamber and a gas exhaust port through which the gas is exhausted. Here, the debris trap includes a first multi-tube and a second multi-tube arranged respectively along a first direction which is a flow direction of the gas traveling from the gas inlet port to the gas exhaust port. Each of the first multi-tube and the second multi-tube includes a plurality of tubes having different maximum outer dimensions in a second direction perpendicular to the first direction. The second multi-tube is arranged downstream of the first multi-tube in the first direction. A number of tubes configuring the second multi-tube is more than a number of tubes configuring the first multi-tube.

An electronic device manufacturing method includes generating extreme ultraviolet light using an extreme ultraviolet light generation apparatus, outputting the extreme ultraviolet light to an exposure apparatus, and exposing a photosensitive substrate to the extreme ultraviolet light in the exposure apparatus to manufacture an electronic device. Here, the extreme ultraviolet light generation apparatus includes a chamber configured to generate plasma by irradiation of a target substance with laser light, an exhaust path including a gas inlet port through which a gas containing debris flows from the chamber and a gas exhaust port through which the gas is exhausted, and a debris trap being arranged on the exhaust path. The debris trap includes a first multi-tube and a second multi-tube arranged respectively along a first direction which is a flow direction of the gas traveling from the gas inlet port to the gas exhaust port. Each of the first multi-tube and the second multi-tube includes a plurality of tubes having different maximum outer dimensions in a second direction perpendicular to the first direction. The second multi-tube is arranged downstream of the first multi-tube in the first direction. A number of tubes configuring the second multi-tube is more than a number of tubes configuring the first multi-tube.

An electronic device manufacturing method includes inspecting a defect of a mask by irradiating the mask with extreme ultraviolet light generated by an extreme ultraviolet light generation apparatus, selecting a mask using a result of the inspection, and exposing and transferring a pattern formed on the selected mask onto a photosensitive substrate. Here, the extreme ultraviolet light generation apparatus includes a chamber configured to generate plasma by irradiation of a target substance with laser light, an exhaust path including a gas inlet port through which a gas containing debris flows from the chamber and a gas exhaust port through which the gas is exhausted, and a debris trap being arranged on the exhaust path. The debris trap includes a first multi-tube and a second multi-tube arranged respectively along a first direction which is a flow direction of the gas traveling from the gas inlet port to the gas exhaust port. Each of the first multi-tube and the second multi-tube includes a plurality of tubes having different maximum outer dimensions in a second direction perpendicular to the first direction. The second multi-tube is arranged downstream of the first multi-tube in the first direction. A number of tubes configuring the second multi-tube is more than a number of tubes configuring the first multi-tube.

### BRIEF DESCRIPTION OF THE DRAWINGS

Embodiments of the present disclosure will be described below merely as examples with reference to the accompanying drawings.

FIG. 1 schematically shows the configuration of an LPP EUV light generation system.

FIG. 2 schematically shows the configuration of an EUV light generation apparatus including a debris trap according to a comparative example.

FIG. 3 is a perspective view of the debris trap according to the comparative example.

FIG. 4 is a sectional view schematically showing the configuration of the debris trap arranged on an exhaust path.

FIG. 5 is a sectional view of the debris trap after use for a certain period of time.

FIG. 6 is a sectional view schematically showing the configuration of the debris trap according to a first embodiment.

FIG. 7 is a front view of a coaxial circular tube trap of first and second stages of the debris trap as viewed in a gas flow direction.

FIG. 8 is a sectional view of the debris trap after use for a certain period of time.

FIG. 9 is a sectional view showing a first modification of the debris trap.

FIG. 10 is a perspective view of a stay applied to the debris trap shown in FIG. 9.

FIG. 11 is a sectional view showing a second modification of the debris trap.

FIG. 12 is a sectional view schematically showing the configuration of the debris trap according to a second embodiment.

FIG. 13 is a front view of a coaxial angular tube trap of the first and second stages of the debris trap as viewed in the gas flow direction.

FIG. 14 schematically shows the configuration of an exposure apparatus connected to the EUV light generation apparatus.

FIG. 15 schematically shows the configuration of an inspection apparatus connected to the EUV light generation apparatus.

### DESCRIPTION OF EMBODIMENTS

### Contents

1. Description of terms
2. Overall description of EUV light generation system
   2.1 Configuration
   2.2 Operation
3. EUV light generation apparatus according to comparative example
   3.1 Configuration
   3.2 Operation
4. Debris trap according to comparative example
   4.1 Configuration
   4.2 Problem
5. First embodiment
   5.1 Configuration
   5.2 Operation
   5.3 Effect
   5.4 First modification
   5.5 Second modification
6. Second embodiment
   6.1 Configuration
   6.2 Operation
   6.3 Effect
7. Electronic device manufacturing method
8. Processor
9. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Terms

A “target” is an object to be irradiated with laser light introduced into a chamber. The target irradiated with laser light is turned into plasma and emits EUV light.

A “droplet” is a form of the target supplied into the chamber. “DL” is an abbreviation for a droplet.

“Plasma light” is radiation light radiated from a target turned into plasma. The radiation light includes EUV light.

“Stannane” is a compound of tin and hydrogen, and is a gas. (Sn+2H₂→SnH₄)

“Debris” is a collective term for a portion of a target substance supplied into the chamber that did not contribute to plasma generation, and ions, atoms, vapor, fine particles, and micro-droplets of the target substance generated in association with plasma generation.

### 2. Overall Description of EUV Light Generation System

### 2.1 Configuration

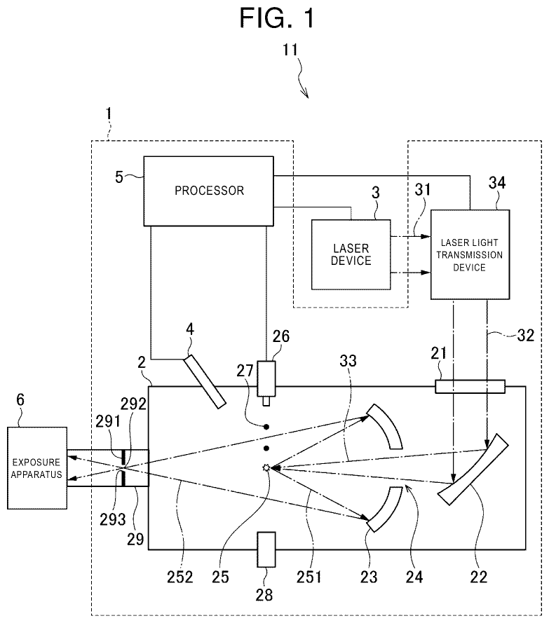

FIG. 1 schematically shows the configuration of an LPP EUV light generation system 11. An EUV light generation apparatus 1 is used together with a laser device 3. In the present disclosure, a system including the EUV light generation apparatus 1 and the laser device 3 is referred to as the EUV light generation system 11.

The EUV light generation apparatus 1 includes a chamber 2 and a target supply unit 26. The chamber 2 is a sealable container. The target supply unit 26 supplies a target substance into the chamber 2. The material of the target substance may include tin, terbium, gadolinium, lithium, xenon, or a combination of any two or more thereof.

A through hole is formed in a wall of the chamber 2. The through hole is blocked by a window 21 through which pulse laser light 32 output from the laser device 3 is transmitted. An EUV light concentrating mirror 23 having a spheroidal reflection surface is arranged in the chamber 2. The EUV light concentrating mirror 23 has a first focal point and a second focal point. A multilayer reflection film in which molybdenum and silicon are alternately stacked is formed on a surface of the EUV light concentrating mirror 23. The EUV light concentrating mirror 23 may be arranged such that the first focal point is located in a plasma generation region 25 and the second focal point is located at an intermediate focal point 292. A through hole 24 is formed at the center of the EUV light concentrating mirror 23, and pulse laser light 33 passes through the through hole 24.

The EUV light generation apparatus 1 includes a processor 5, a target sensor 4, and the like. The target sensor 4 detects at least one of the presence, trajectory, position, and velocity of the target 27. The target sensor 4 may have an imaging function.

Further, the EUV light generation apparatus 1 includes a connection portion 29 providing communication between the internal space of the chamber 2 and the internal space of an exposure apparatus 6. A wall 291 in which an aperture 293 is formed is provided in the connection portion 29. The wall 291 is arranged such that an opening of the aperture 293 is located at the second focal point of the EUV light concentrating mirror 23.

Further, the EUV light generation apparatus 1 includes a laser light transmission device 34, a laser light concentrating mirror 22, a target collection device 28 for collecting the target 27, and the like. The laser light transmission device 34 includes an optical element for defining a transmission state of laser light, and an actuator for adjusting the position, posture, and the like of the optical element.

### 2.2 Operation

Operation of the EUV light generation system 11 will be described with reference to FIG. 1. Pulse laser light 31 output from the laser device 3 enters, via the laser light transmission device 34, the chamber 2 through the window 21 as the pulse laser light 32. The pulse laser light 32 travels along a laser light path in the chamber 2, is reflected by the laser light concentrating mirror 22, and is radiated to the target 27 as the pulse laser light 33.

The target supply unit 26 outputs the target 27 formed of a target substance toward the plasma generation region 25 in the chamber 2. The target 27 is irradiated with the pulse laser light 33. The target 27 irradiated with the pulse laser light 33 is turned into plasma, and radiation light 251 is radiated from the plasma. EUV light 252 contained in the radiation light 251 is selectively reflected by the EUV light concentrating mirror 23. The EUV light 252 reflected by the EUV light concentrating mirror 23 is concentrated at the intermediate focal point 292 and output to the exposure apparatus 6. Here, one target 27 may be irradiated with a plurality of pulses included in the pulse laser light 33.

The processor 5 is configured to control the entire EUV light generation system 11. The processor 5 processes image data or the like of the target 27 imaged by the target sensor 4. Further, the processor 5 performs, for example, at least one of control of the timing at which the target 27 is output and control of the output direction of the target 27. Further, the processor 5 performs, for example, at least one of control of the oscillation timing of the laser device 3, control of the travel direction of the pulse laser light 32, and control of the concentration position of the pulse laser light 33. The above-described various kinds of control are merely examples, and other control may be added as necessary.

### 3. EUV Light Generation Apparatus According to Comparative Example

### 3.1 Configuration

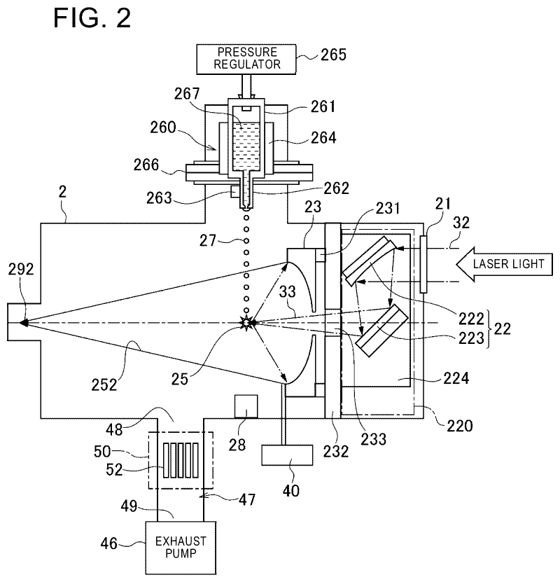

The configuration of the EUV light generation apparatus 1 according to a comparative example will be described with reference to FIG. 2. The comparative example of the present disclosure is an example recognized by the applicant as known only by the applicant, and is not a publicly known example admitted by the applicant.

The EUV light generation apparatus 1 includes the chamber 2, a target generator 260, a laser light concentrating optical system 220, the EUV light concentrating mirror 23, a gas supply unit 40, a debris trap 50, and an exhaust pump 46. The target generator 260 includes a tank 261, a nozzle 262, a piezoelectric element 263, a heater 264, and a pressure regulator 265. A target substance 267 is stored in the tank 261.

The heater 264 is arranged on the outer wall of the tank 261, and the target substance 267 in the tank 261 is heated by the heater 264 to be melted. The target substance 267 is, for example, tin (Sn).

The pressure regulator 265 is connected to the tank 261 via a pipe. The pressure in the tank 261 is adjusted by the pressure regulator 265. The pressure regulator 265 includes therein a solenoid valve for supply and exhaust of a gas, a pressure sensor, and the like. The pressure regulator 265 is connected to a gas cylinder (not shown) filled with an inert gas such as helium or argon. The inert gas is supplied from the gas cylinder into the tank 261 via the pressure regulator 265. The pressure regulator 265 can increase or decrease the pressure in the tank 261 by supplying a gas into the tank 261 or exhausting a gas from the tank 261.

The nozzle 262 communicates with the tank 261, and the molten target substance 267 is output from a nozzle hole of the nozzle 262. The plasma generation region 25 in the chamber 2 is located on the extension line of the center axis direction of the nozzle 262.

The target generator 260 forms droplets with, for example, a continuous jet method. In the continuous jet method, the nozzle 262 is vibrated to give standing waves to the flow of the target 27 ejected in a jet form, thereby periodically separating the target 27. The separated target 27 may form a free interface by its surface tension to form droplets.

The piezoelectric element 263 as a means for vibrating the nozzle 262 is fixed to an outer side surface portion of the nozzle 262 having a pipe shape. The flow of the target substance 267 ejected in a jet form from the nozzle 262 is periodically divided by the vibration of the piezoelectric element 263, thereby forming droplets. The target generator 260 is an example of the target supply unit 26 (FIG. 1).

The target generator 260 is arranged in the chamber 2 via a stage 266. The stage 266 is a mechanism for adjusting the position of the target generator 260 so that the target 27 output from the target generator 260 is supplied to the plasma generation region 25. The stage 266 may be, for example, a two-axis stage with an actuator capable of moving the target generator 260 in two axis directions perpendicular to each other.

The laser light concentrating optical system 220 is an optical system that concentrates the pulse laser light 32 introduced into the chamber 2 through the window 21 on the plasma generation region 25. The laser light concentrating optical system 220 is arranged in the chamber 2. The laser light concentrating optical system 220 includes a high reflection off-axis parabolic mirror 222, a high reflection planar mirror 223, and a plate 224.

Each of the high reflection off-axis parabolic mirror 222 and the high reflection planar mirror 223 is held by a mirror holder and fixed to the plate 224. Each optical element is arranged such that the concentration position of the laser light concentrating optical system 220 substantially coincides with the plasma generation region 25. The high reflection off-axis parabolic mirror 222 and the high reflection planar mirror 223 are an example of the laser light concentrating mirror 22 (FIG. 1).

The EUV light concentrating mirror 23 is held by an EUV light concentrating mirror holder 231 and fixed to a plate 232. The plate 232 is fixed to the inner wall of the chamber 2. The plate 232 includes a through hole 233 through which the pulse laser light 33 reflected by the laser light concentrating optical system 220 passes toward the plasma generation region 25.

The pulse laser light 32 output from the laser device 3 is concentrated, via the window 21 and the laser light concentrating optical system 220, and radiated to the target 27 supplied to the chamber 2 by the target generator 260, so that plasma that emits EUV light 252 is generated.

The EUV light 252 is collected by the EUV light concentrating mirror 23 and output to an external apparatus such as the exposure apparatus 6 via the intermediate focal point 292. Of the targets 27 output from the target generator 260 into the chamber 2, the targets 27 that have not been irradiated with the pulse laser light 33 are collected by the target collection device 28.

The gas supply unit 40 and the exhaust pump 46 are connected to the chamber 2. The gas supply unit 40 supplies an etching gas that reacts with debris floating in the chamber 2 and debris adhering to the inside of the chamber 2. When the target substance 267 is tin, the etching gas may be a hydrogen gas. The exhaust pump 46 exhausts a reactant of the debris and the etching gas and an unreacted etching gas to the outside of the chamber 2. A vacuum pump may be used as the exhaust pump 46. A detoxification device (not shown) may be connected to an output portion of the exhaust pump 46.

An exhaust path 47 which is a gas flow path between the exhaust pump 46 and the chamber 2 includes a gas inlet port 48 through which a gas containing debris flows from the chamber 2, and a gas exhaust port 49 through which the gas is exhausted. The gas exhaust port 49 is connected to the exhaust pump 46, and the debris trap 50 is arranged in the middle of the exhaust path 47.

The debris trap 50 includes a plurality of blades 52 arranged parallel to the flow direction of the gas traveling from the gas inlet port 48 to the gas exhaust port 49. The blades 52 may be flat plate-shaped members, curved plates, or cylindrical members.

### 3.2 Operation

Generation operation of the EUV light 252 in the EUV light generation apparatus 1 is as described with reference to FIG. 1. The etching gas and the reactant in the chamber 2 are guided to the debris trap 50 by the exhaust pump 46. When the target 27 is tin and the etching gas is a hydrogen gas, the reactant includes stannane (SnH₄).

Stannane is decomposed upon contact with the blades 52 to deposit tin as the target substance. The deposited tin is collected through adhesion to the blades 52.

### 4. Debris Trap According to Comparative Example

### 4.1 Configuration

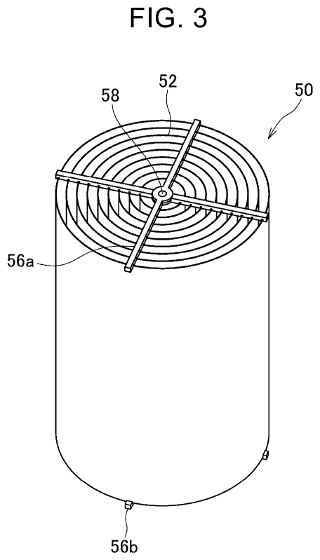

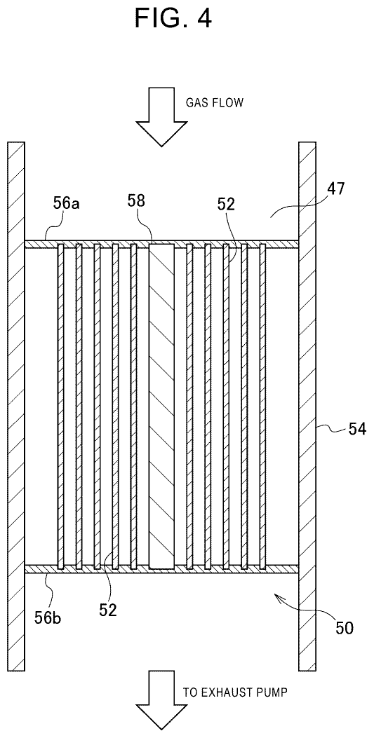

FIG. 3 is a perspective view of the debris trap 50 according to the comparative example. FIG. 4 is a sectional view of the debris trap 50 arranged on the exhaust path 47.

The debris trap 50 is a coaxial circular tube trap having a multi-tube structure in which a plurality of circular tube-shaped blades 52 with different diameters are arranged concentrically. A “tube” is synonymous with a “cylinder”.

The debris trap 50 may include a housing 54 that accommodates the plurality of blades 52 and forms a part of the exhaust path 47. The housing 54 functions as a container that accommodates the plurality of blades 52, and also functions as a flow path tube of the exhaust path 47. In FIG. 3, the housing 54 is omitted. Each of the blades 52 is arranged such that the side surface of the circular tube extends along the flow direction of the gas. The flow direction of the gas in the exhaust path 47 is referred to as the “gas flow direction”, and a direction perpendicular to the gas flow direction is referred to as a “gas flow perpendicular direction”.

The plurality of blades 52 are positioned and fixed by rod-shaped stays 56a, 56b arranged upstream and downstream in the gas flow direction. The stays 56a, 56b may have cutouts for fixing the blades 52. The stays 56a, 56b upstream and downstream of the blades 52 may be held by a shaft 58. Alternatively, the blades 52 may be welded to the stays 56a, 56b. Alternatively, a plurality of spacers for fixing the blades 52 may be arranged parallel to the radial direction of the blades 52, and the blades 52 may be fixed to the spacers.

The debris trap 50 is arranged in a portion of the pipe of the exhaust path 47 where the temperature of the gas flowing through the debris trap 50 is 20° C. to 70° C. Alternatively, the EUV light generation apparatus 1 is operated under an operation condition in which the temperature of the gas flowing through the debris trap 50 is 20° C. to 70° C. by adjusting the laser output or the like.

Neither a heater nor a temperature sensor is arranged in the debris trap 50. The temperature of the blades 52 depends on the temperature of the gas flowing into the debris trap 50 and ranges from 20° C. to 70° C. When it is assumed that a part of the target substance adhering to the blades 52 is to peel off, a collection unit of the target substance may be provided below the blades 52 in the gravity direction. The collection unit may be configured as a space deviated from the path of the gas flow. The collection unit may not include a heater.

### 4.2 Problem

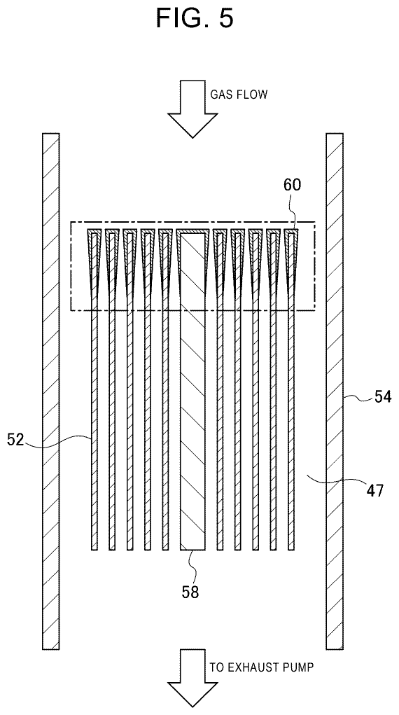

FIG. 5 is a sectional view of the debris trap 50 after use for a certain period of time. In FIG. 5, a cross-section without the stays 56a, 56b is shown. Metal tin 60 is deposited on the surfaces of the blades 52 of the debris trap 50, so that tin in the exhaust gas is collected. Here, the metal tin 60 also adheres to the shaft 58 and the stay 56a.

Therefore, when the EUV light generation apparatus 1 is operated for a long period of time, the metal tin 60 deposited on the surfaces of the blades 52 eventually narrows the exhaust path 47. When the exhaust path 47 is narrowed, the exhaust resistance increases, and it may be difficult to maintain the pressure in the chamber 2 at a predetermined value. When the pressure in the chamber 2 increases, the transmittance of the EUV light 252 may decrease, resulting in insufficient output.

The thickness of the metal tin 60 adhering to the blades 52 begins to increase on the upstream side, and when the flow path at the upstream side of the blades 52 is narrowed, the debris trap 50 needs to be cleaned or replaced. At this time, the downstream side of the blades 52 often still has an area in which metal tin can be collected. That is, as in the portion surrounded by a dashed-dotted line in FIG. 5, a large amount of the metal tin 60 adheres to the upstream ends of the blades 52, and the path of the gas flow tends to be narrowed.

In order to extend the operation time of the EUV light generation apparatus 1, it is necessary to have a configuration in which the maintenance interval of the debris trap 50 is extended, narrowing of the flow path at the upstream side of the blade 52 is suppressed, and tin can be collected in a region at the downstream side as well.

### 5. First Embodiment

### 5.1 Configuration

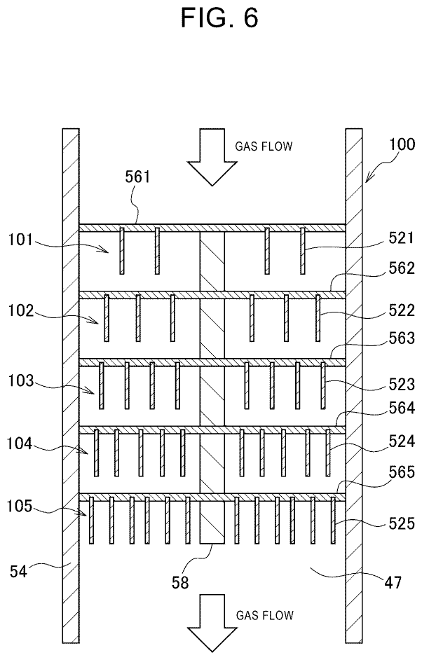

FIG. 6 is a sectional view schematically showing the configuration of a debris trap 100 according to a first embodiment. The debris trap 100 has a multi-stage trap structure in which a plurality of coaxial circular tube traps 101, 102, 103, 104, 105 are arranged at intervals in the gas flow direction. In FIG. 6, an example of a five-stage trap structure is shown, but the number of stages of the trap is not limited to five, and can be designed to any number of two or more. Here, in order to sufficiently remove debris, the number of stages of the trap is preferably three or more.

The coaxial circular tube traps 101, 102, 103, 104, 105 each have a plurality of corresponding circular tube-shaped blades 521, 522, 523, 524, 525 having different diameters arranged concentrically forming a multi-tube structure. The outer circumferential shape of the circular tube-shaped blade is an example of the “circular tube shape” in the present disclosure.

FIG. 6 shows an example in which, from the upstream side in the gas flow direction, the first-stage coaxial circular tube trap 101 has a double-tube blade, the second-stage coaxial circular tube trap 102 has a triple-tube blade, the third-stage coaxial circular tube trap 103 has a quadruple-tube blade, the fourth-stage coaxial circular tube trap 104 has a quintuple-tube blade, and the fifth-stage coaxial circular tube trap 105 has a sextuple-tube blade, but the number of blades (number of layers of the multi-tube) configuring the trap at each stage is not limited to the example of FIG. 6. The coaxial circular tube trap 101 is an example of the “first multi-tube” in the present disclosure, and the coaxial circular tube trap 102 is an example of the “second multi-tube” in the present disclosure. Each of the coaxial circular tube traps 103, 104, 105 is an example of the “third multi-tube” in the present disclosure. Each of the blades 521, 522, 523, 524, 525 is an example of the “tube” in the present disclosure. The gas flow direction from top to bottom in FIG. 6 is an example of the “first direction” in the present disclosure, and the gas flow perpendicular direction is an example of the “second direction” in the present disclosure.

The plurality of blades 521, 522, 523, 524, 525 configuring stages of the coaxial circular tube traps 101, 102, 103, 104, 105 may be held by stays 561, 562, 563, 564, 565, respectively. The stays 561, 562, 563, 564, 565 may be held by the shaft 58.

The plurality of coaxial circular tube traps 101, 102, 103, 104, 105 are coaxially arranged with the center axes thereof matched. The interval between the adjacent coaxial circular tube traps 101, 102, 103, 104, 105 is set to a distance allowing the adjacent blades 521, 522, 523, 524, 525 in the gas flow direction not to contact to each other even when metal tin adheres to the upstream ends of the blades 521, 522, 523, 524, 525 in the gas flow direction in the traps. For example, the interval between the adjacent coaxial circular tube traps 101, 102, 103, 104, 105 may be 10 mm.

The number of blades may be increased toward the downstream side in the gas flow direction, for example, increasing by one blade per stage as shown in FIG. 6. Alternatively, stages of traps with the same number blades may be consecutive.

The number of the blades 521, 522, 523, 524, 525 included in each of the coaxial circular tube traps 101, 102, 103, 104, 105 increases toward the downstream side, and the interval between the blades (the gap between tubes configuring the circular multi-tube) in the trap of each stage becomes smaller toward the downstream side.

When focusing on the first-stage coaxial circular tube trap 101 and the second-stage coaxial circular tube trap 102, the interval between the closest blades among the plurality of blades 522 configuring the second-stage coaxial circular tube trap 102 being on the downstream side is smaller than the interval between the closest blades among the plurality of blades 521 configuring the first-stage coaxial circular tube trap 101. The traps in the third and subsequent stages have a similar relationship between the trap relatively on the upstream side and the trap relatively on the downstream side. The interval between the closest blades among the plurality of blades 521 configuring the coaxial circular tube trap 101 is an example of the “interval between tubes closest to each other among a plurality of tubes configuring a first multi-tube” in the present disclosure, and the interval between the closest blades among the plurality of blades 522 configuring the coaxial circular tube trap 102 is an example of the “interval between tubes closest to each other among a plurality of tubes configuring a second multi-tube” in the present disclosure.

Further, even when the blades 521, 522, 523, 524, 525 are extended in the axis direction, they do not overlap with other blades on the upstream side and the downstream side. That is, the diameters of the blades 521, 522, 523, 524, 525 are different from each other so that projection images of the blades 521, 522, 523, 524, 525 in the axis direction do not overlap each other. The “diameter” here may be the outer diameter of the circular tube-shaped blade. The “outer diameter” is an example of the maximum outer dimension in the gas flow perpendicular direction.

The thickness (wall thickness) and the length in the gas flow direction of each of the plurality of blades 521, 522, 523, 524, 525 are not particularly limited. The thickness of each of the blades 521, 522, 523, 524, 525 may be, for example, 0.1 mm or more and 2.0 mm or less. The thickness of each of the blades 521, 522, 523, 524, 525 may be the same or blades with different thicknesses may be mixed.

The length of each of the blades 521, 522, 523, 524, 525 in the gas flow direction may be the same or blades with different lengths may be used for each stage.

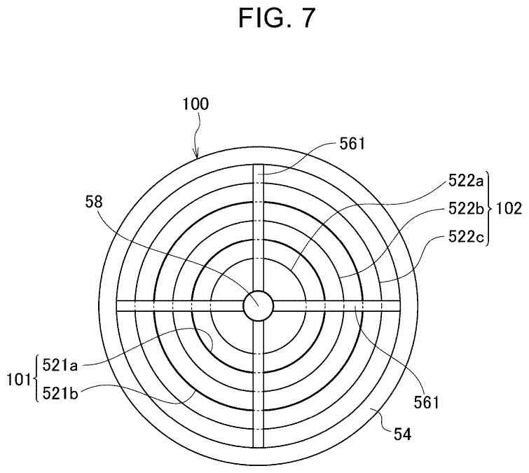

FIG. 7 is a front view of the coaxial circular tube traps 101, 102 of the first and second stages of the debris trap 100 as viewed in the gas flow direction. The first-stage coaxial circular tube trap 101 has a configuration in which two circular tube blades 521a, 521b with different diameters are arranged coaxially. The second-stage coaxial circular tube trap 102 has a configuration in which three circular tube blades 522a, 522b, 522c with different diameters are arranged coaxially. Each of the circular tube blades 521a, 521b is the blade 521 of FIG. 6, and each of the circular tube blades 522a, 522b, 522c is the blade 522 of FIG. 6. The coaxial circular tube trap 101 is an example of the “plurality of tubes” of the first multi-tube in the present disclosure, and the coaxial circular tube trap 102 is an example of the “plurality of tubes” of the second multi-tube in the present disclosure.

The circular tube blades 521a, 521b, 522a, 522b, 522c of each corresponding stage are arranged in a nested manner with blades with a smaller diameter arranged inside blades with a larger diameter. The outer diameter of the circular tube blade 522c, which is the outermost tube of the second stage, is larger than the outer diameter of the circular tube blade 521b, which is the outermost tube of the first stage. The outer diameter of the circular tube blade 522a, which is the innermost tube of the second stage, is smaller than the outer diameter of the circular tube blade 521a, which is the innermost tube of the first stage. The blade interval of the circular tube blades 522a, 522b, 522c of the second stage is narrower than the blade interval of the circular tube blades 521a, 521b of the first stage. The blade interval of the circular tube blades 521a, 521b is an example of the “interval between adjacent tubes among the plurality of tubes configuring the first multi-tube” in the present disclosure, and the blade interval of the circular tube blades 522a, 522b, 522c is an example of “the interval between adjacent tubes among the plurality of tubes configuring the second multi-tube” in the present disclosure. The circular tube blade 521b is an example of the “first outermost tube” in the present disclosure, and the circular tube blade 522c is an example of the “second outermost tube” in the present disclosure. The circular tube blade 521a is an example of the “first innermost tube” in the present disclosure, and the circular tube blade 522a is an example of the “second innermost tube” in the present disclosure.

In FIG. 7, only the coaxial circular tube traps 101, 102 of the first and second stages are shown, but the third and subsequent stages also have a similar relationship between upstream and downstream traps.

The coaxial circular tube traps 101, 102, 103, 104, 105 of the stages may be configured to be individually replaceable, but may also be configured to be replaced collectively as a whole. Each of the coaxial circular tube traps 101, 102, 103, 104, 105 is formed of a metal such as stainless steel, aluminum, nickel, or copper.

In the EUV light generation apparatus 1, the debris trap 100 is applied instead of the debris trap 50 shown in FIGS. 3 and 4.

### 5.2 Operation

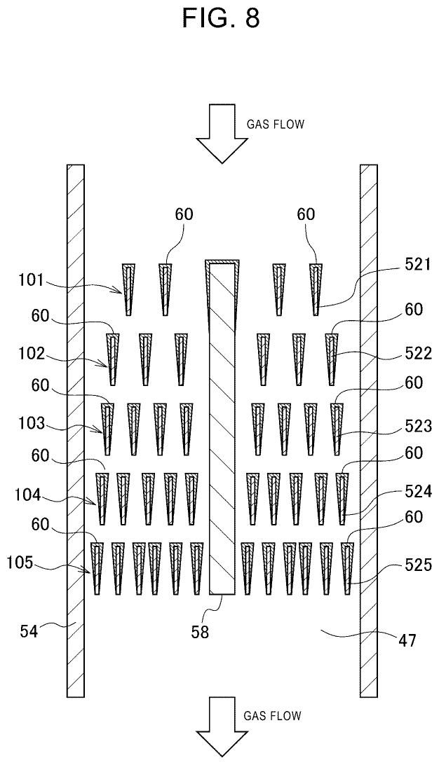

FIG. 8 is a sectional view of the debris trap 100 after use for a certain period of time. FIG. 8 shows a cross-section without the stays 561, 562, 563, 564, 565. When the exhaust gas from the chamber 2 passes through the debris trap 100 in the exhaust path 47, since the exhaust gas flows into the downstream trap after the metal tin 60 is deposited at the upstream trap, the density of tin contained in the exhaust gas becomes lower toward the downstream side.

Therefore, the thickness of tin adhering to each of the coaxial circular tube traps 101, 102, 103, 104, 105 per unit time is larger at traps arranged upstream in the gas flow direction, and smaller at traps arranged downstream.

The arrangement density of the blades 521, 522, 523, 524, 525 in each of the coaxial circular tube traps 101, 102, 103, 104, 105 is sparser toward the upstream side and denser toward the downstream side. Therefore, narrowing of the flow path (decrease in the sectional area of the flow path) proceeds substantially uniformly between the traps on the upstream side where the blade interval is large and the traps on the downstream side where the blade interval is small.

### 5.3 Effect

According to the debris trap 100 of the first embodiment, narrowing of the flow path proceeds substantially uniformly between the traps on the upstream side and the traps on the downstream side, so that it is possible to suppress the occurrence of narrowing only on the upstream side.

Further, since the projection images of the blades 521, 522, 523, 524, 525 in the axis direction do not overlap each other, the blades on the downstream side are less overlapped with a region having a low tin density behind the blades on the upstream side. As a result, tin can be effectively collected at the traps on the downstream side.

As described above, in the debris trap 100 according to the first embodiment, the maintenance interval of the debris trap 100 can be extended as extending the time until the pressure loss caused by the debris trap 100 affects operation of the EUV light generation apparatus 1.

### 5.4 First Modification

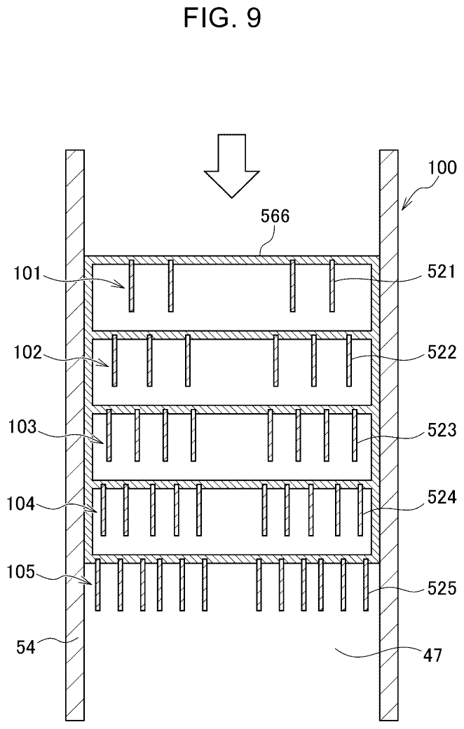

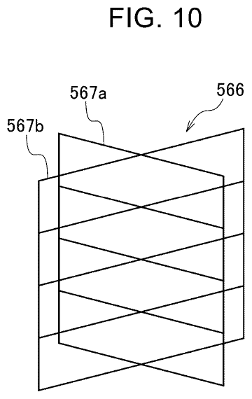

FIG. 9 is a sectional view showing a first modification of the debris trap 100, and FIG. 10 is a perspective view of a stay 566 applied to the debris trap 100 shown in FIG. 9. Instead of the stays 561, 562, 563, 564, 565 shown in FIG. 6, the stay 566 configured by combining lattice-shaped members 567a, 567b shown in FIG. 10 may be used. In this case, the shaft 58 may not be provided.

### 5.5 Second Modification

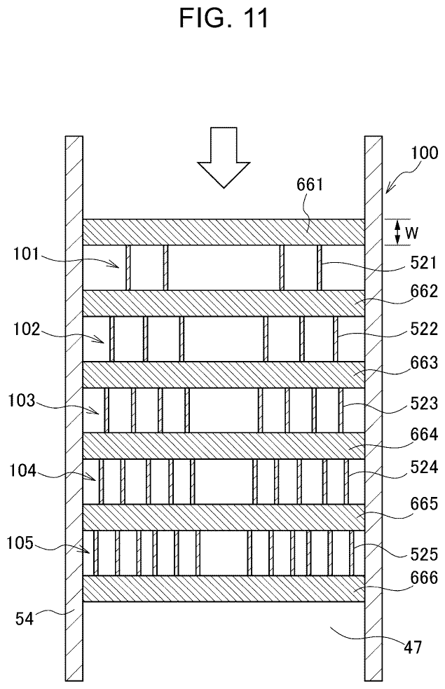

FIG. 11 is a sectional view showing a second modification of the debris trap 100. Instead of the stays 561, 562, 563, 564, 565 shown in FIG. 6, plate-shaped stays 661, 662, 663, 664, 665, 666 shown in FIG. 11 may be used. That is, the stays 661, 662, 663, 664, 665, 666 may each be formed of a plate-shaped member having a predetermined width W, and the plurality of plate-shaped stays 661, 662, 663, 664, 665, 666 may be configured to hold the upstream and downstream blades 521, 522, 523, 524, 525.

The plate-shaped stays 661, 662, 663, 664, 665, 666 are each arranged such that the side surface thereof having the width W is parallel to the gas flow direction. In this case as well, the shaft 58 may not be provided.

### 6. Second Embodiment

### 6.1 Configuration

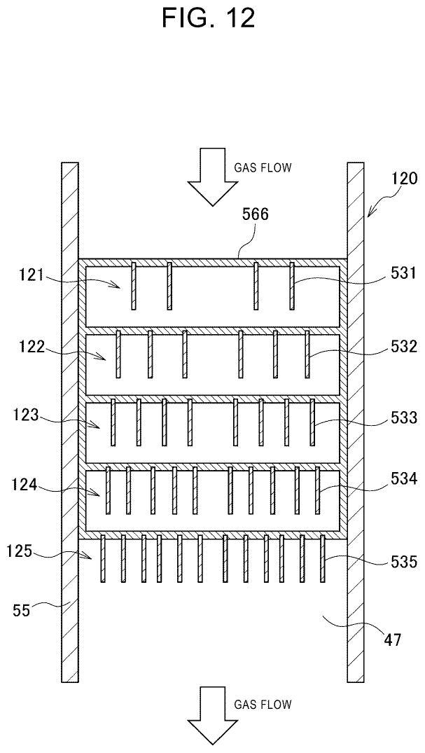

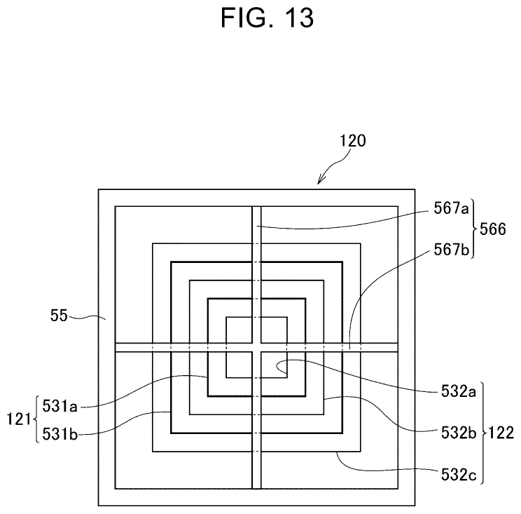

FIG. 12 is a sectional view schematically showing the configuration of a debris trap 120 according to a second embodiment. FIG. 13 is a front view of coaxial angular tube traps 121, 122 of the first and second stages of the debris trap 120 as viewed in the gas flow direction. The debris trap 120 will be described in terms of differences from the debris trap 100 according to the first embodiment. The shape of each blade configuring the multi-stage trap structure is not limited to a circular tube. For example, instead of blades each being a circular tube, blades each being a polygonal tube having a polygonal outer circumferential shape of a cross-section perpendicular to the gas flow direction may be used. The outer circumferential shape of polygonal tube blades is an example of a “polygonal tube shape” in the present disclosure.

The sectional shape of the angular tube may be a polygon that matches the sectional shape of the exhaust path 47. For example, when the sectional shape of the exhaust path 47 is a rectangle, the sectional shape of the angular tube may be a rectangle. Here, the term “polygon” includes a shape that can be practically regarded as a polygon. The same applies to the term “rectangle”. For example, a rounded rectangle with rounded corners at the four corners of a rectangle may be included in the concept of a rectangle.

The debris trap 120 includes the coaxial angular tube traps 121, 122, 123, 124, 125 instead of the coaxial circular tube traps 101, 102, 103, 104, 105 of FIG. 6. The coaxial angular tube traps 121, 122, 123, 124, 125 each have a plurality of corresponding angular tube-shaped blades 531, 532, 533, 534, 535 having different maximum outer dimensions in the gas flow perpendicular direction arranged coaxially forming a multi-tube structure. In the case in which the sectional shape of the cross-section perpendicular to the gas flow direction is an angular tube having a rectangle, the outer dimension in the diagonal direction of the rectangle sectional shape may be the “maximum outer dimension in the gas flow perpendicular direction”.

The blades 531, 532, 533, 534, 535 configuring the corresponding coaxial angular tube trap 121, 122, 123, 124, 125 may be held in a constant interval from one another by the stay 566. When the stay 566 as shown in FIG. 10 is employed, the shaft 58 may be omitted. Instead of the stay 566, stays 561, 562, 563, 564, 565 shown in FIG. 6 or stays 661, 662, 663, 664, 665, 666 shown in FIG. 11 may be employed.

The debris trap 120 includes a housing 55 that forms a part of the exhaust path 47 instead of the housing 54 shown in FIG. 6. The housing 55 has a rectangular sectional shape in a cross-section perpendicular to the gas flow direction.

As shown in FIG. 13, the first-stage coaxial angular tube trap 121 has a configuration in which two angular tube blades 531a, 531b with different maximum outer dimensions in the gas flow perpendicular direction are arranged coaxially. The second-stage coaxial angular tube trap 122 has a configuration in which three angular tube blades 532a, 532b, 532c with different maximum outer dimensions in the gas flow perpendicular direction are arranged coaxially. The angular tube blades 531a, 531b, 532a, 532b, 532c of each corresponding stage are arranged in a nested manner with blades with a smaller maximum external dimension arranged inside blades with a larger maximum external dimension. Each of the angular tube blades 531a, 531b is the blade 531 of FIG. 12, and each of the angular tube blades 532a, 532b, 532c is the blade 532 of FIG. 12.

The outer circumferential shapes of the angular tube blades 531a, 531b, 532a, 532b, 532c in a cross-section perpendicular to the gas flow direction may be similar. Further, the outer circumferential shapes of the angular tube blades 531a, 531b, 532a, 532b, 532c in a cross-section perpendicular to the gas flow direction may be similar to the shape of the flow path cross-section of the exhaust path 47. That is, the outer circumferential shapes of the angular tube blades 531a, 531b, 532a, 532b, 532c in the cross-section perpendicular to the gas flow direction may be similar to the inner circumferential shape of the cross-section perpendicular to the gas flow direction of the housing 55. The same applies to the third and subsequent stages of the coaxial angular tube traps 123, 124, 125. Other configuration is similar to that in the first embodiment.

### 6.2 Operation

Operation of the debris trap 120 is similar to operation of the debris trap 100.

### 6.3 Effect

According to the second embodiment, effects similar to the first embodiment can be obtained. Similarly to the debris trap 120, by designing the shapes of the trap and the blades of each stage in accordance with the sectional shape of the exhaust path 47, the space utilization of the exhaust path 47 is improved, and thus a compact debris trap 120 can be realized.

### 7. Electronic Device Manufacturing Method

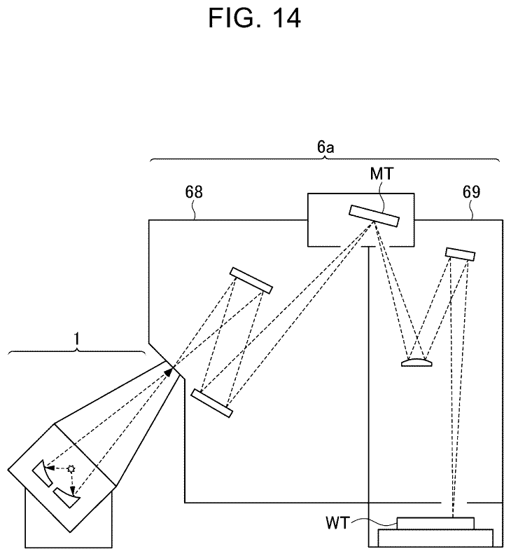

FIG. 14 schematically shows the configuration of an exposure apparatus 6a connected to the EUV light generation apparatus 1. The EUV light generation apparatus 1 includes the debris trap 100 or the debris trap 120. In FIG. 14, the exposure apparatus 6a as the external apparatus includes a mask irradiation unit 68 and a workpiece irradiation unit 69. The mask irradiation unit 68 illuminates, via a reflection optical system, a mask pattern of the mask table MT with the EUV light entering from the EUV light generation apparatus 1. The workpiece irradiation unit 69 images the EUV light reflected by the mask table MT onto a workpiece (not shown) arranged on a workpiece table WT via the reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

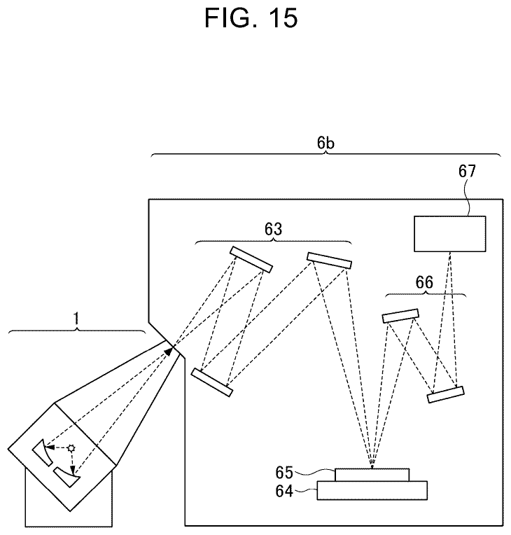

FIG. 15 schematically shows the configuration of an inspection apparatus 6b connected to the EUV light generation apparatus 1. In FIG. 15, an inspection apparatus 6b as the external apparatus includes an illumination optical system 63 and a detection optical system 66. The illumination optical system 63 reflects the EUV light entering from the EUV light generation apparatus 1 to illuminate a mask 65 placed on a mask stage 64. Here, the mask 65 conceptually includes a mask blanks before a pattern is formed. The detection optical system 66 reflects the EUV light from the illuminated mask 65 and forms an image on a light receiving surface of a detector 67. The detector 67 having received the EUV light acquires an image of the mask 65. The detector 67 is, for example, a time delay integration (TDI) camera. Inspection for a defect of the mask 65 is performed based on the image of the mask 65 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 6a.

### 8. Processor

A processor such as the processor 5 may be physically configured as hardware to execute various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes may be defined by the control program as an aggregation thereof. The processing device may be a general-purpose processing device such as a central processing unit (CPU) or a special-purpose processing device such as a graphics processing unit (GPU).

Alternatively, the processor may be programmed as software to execute the various processes included in the present disclosure. For example, the processor may have a function of executing various processes implemented in a dedicated device such as an application specific integrated circuit (ASIC) or a programmable device such as a field programmable gate array (FPGA).

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 9. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A debris trap arranged on an exhaust path including a gas inlet port through which a gas containing debris flows from a chamber and a gas exhaust port through which the gas is exhausted,
the debris trap comprising a first multi-tube and a second multi-tube arranged respectively along a first direction which is a flow direction of the gas traveling from the gas inlet port to the gas exhaust port,
each of the first multi-tube and the second multi-tube including a plurality of tubes having different maximum outer dimensions in a second direction perpendicular to the first direction,
the second multi-tube being arranged downstream of the first multi-tube in the first direction, and
a number of tubes configuring the second multi-tube being more than a number of tubes configuring the first multi-tube.

2. The debris trap according to claim 1,
wherein the debris is tin.

3. The debris trap according to claim 1,
wherein an interval between tubes closest to each other among the plurality of tubes configuring the second multi-tube is smaller than an interval between tubes closest to each other among the plurality of tubes configuring the first multi-tube.

4. The debris trap according to claim 1,
wherein the plurality of tubes are arranged in a nested manner.

5. The debris trap according to claim 1,
wherein each of the plurality of tubes has a circular tube shape or a polygonal tube shape.

6. The debris trap according to claim 1,
wherein center axes of the first multi-tube and the second multi-tube are matched.

7. The debris trap according to claim 1,
wherein outer circumferential shapes of the plurality of tubes in a cross-section perpendicular to the first direction are similar to each other.

8. The debris trap according to claim 1,
wherein outer circumferential shapes of the plurality of tubes in a cross-section perpendicular to the first direction are similar to a shape of a flow path cross-section of the exhaust path.

9. The debris trap according to claim 1,
comprising a housing that accommodates the first multi-tube and the second multi-tube.

10. The debris trap according to claim 9,
wherein the housing forms a part of a flow path tube of the exhaust path.

11. The debris trap according to claim 9,
wherein outer circumferential shapes of the plurality of tubes in a cross-section perpendicular to the first direction are similar to an inner circumferential shape of the housing in a cross-section perpendicular to the first direction.

12. The debris trap according to claim 1,
wherein the first multi-tube and the second multi-tube are arranged at an interval in the first direction.

13. The debris trap according to claim 1,
wherein a projection image obtained by projecting the plurality of tubes configuring the first multi-tube in an axis direction does not overlap a projection image obtained by projecting the plurality of tubes configuring the second multi-tube in the axis direction.

14. The debris trap according to claim 1,
wherein an interval between adjacent tubes among the plurality of tubes configuring the first multi-tube is larger than an interval between adjacent tubes among the plurality of tubes configuring the second multi-tube.

15. The debris trap according to claim 1,
wherein the maximum outer dimension in the second direction of a first outermost tube arranged outermost among the plurality of tubes configuring the first multi-tube is smaller than the maximum outer dimension in the second direction of a second outermost tube arranged outermost among the plurality of tubes configuring the second multi-tube, and
the maximum outer dimension in the second direction of a first innermost tube arranged innermost among the plurality of tubes configuring the first multi-tube is larger than the maximum outer dimension in the second direction of a second innermost tube arranged innermost among the plurality of tubes configuring the second multi-tube.

16. The debris trap according to claim 1,
comprising a stay that holds the plurality of tubes.

17. The debris trap according to claim 1,
further comprising a third multi-tube arranged along the first direction and including a plurality of tubes having different maximum outer dimensions in the second direction,
wherein the third multi-tube is arranged downstream of the second multi-tube in the first direction, and
a number of tubes configuring the third multi-tube is more than the number of tubes configuring the second multi-tube.

18. An extreme ultraviolet light generation apparatus comprising:
a chamber configured to generate plasma by irradiation of a target substance with laser light;
an exhaust path including a gas inlet port through which a gas containing debris flows from the chamber and a gas exhaust port through which the gas is exhausted; and
the debris trap according to claim 1 arranged on the exhaust path.

19. An electronic device manufacturing method, comprising:
generating extreme ultraviolet light using an extreme ultraviolet light generation apparatus;
outputting the extreme ultraviolet light to an exposure apparatus; and
exposing a photosensitive substrate to the extreme ultraviolet light in the exposure apparatus to manufacture an electronic device,
the extreme ultraviolet light generation apparatus including:
a chamber configured to generate plasma by irradiation of a target substance with laser light;
an exhaust path including a gas inlet port through which a gas containing debris flows from the chamber and a gas exhaust port through which the gas is exhausted; and
a debris trap being arranged on the exhaust path,
the debris trap including a first multi-tube and a second multi-tube arranged respectively along a first direction which is a flow direction of the gas traveling from the gas inlet port to the gas exhaust port,
each of the first multi-tube and the second multi-tube including a plurality of tubes having different maximum outer dimensions in a second direction perpendicular to the first direction,
the second multi-tube being arranged downstream of the first multi-tube in the first direction, and
a number of tubes configuring the second multi-tube being more than a number of tubes configuring the first multi-tube.

20. An electronic device manufacturing method, comprising:
inspecting a defect of a mask by irradiating the mask with extreme ultraviolet light generated by an extreme ultraviolet light generation apparatus;
selecting a mask using a result of the inspection; and
exposing and transferring a pattern formed on the selected mask onto a photosensitive substrate,
the extreme ultraviolet light generation apparatus including:
a chamber configured to generate plasma by irradiation of a target substance with laser light;
an exhaust path including a gas inlet port through which a gas containing debris flows from the chamber and a gas exhaust port through which the gas is exhausted; and
a debris trap being arranged on the exhaust path,
the debris trap including a first multi-tube and a second multi-tube arranged respectively along a first direction which is a flow direction of the gas traveling from the gas inlet port to the gas exhaust port,
each of the first multi-tube and the second multi-tube including a plurality of tubes having different maximum outer dimensions in a second direction perpendicular to the first direction,
the second multi-tube being arranged downstream of the first multi-tube in the first direction, and
a number of tubes configuring the second multi-tube being more than a number of tubes configuring the first multi-tube.
